(19) United States
(12) Patent Application Publication
(10) Pub. No.: US 2007/0222493 A1
(43) Pub. Date: Sep. 27, 2007

(54) Digital-to-time converter

(75) Inventors: Themistokles Afentakis, Vancouver, WA (US); Apostolos T. Voutsas, Portland, OR (US); Paul J. Schuele, Washougal, WA (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(73) Assignee: Sharp Laboratories of America, Inc.

(21) Appl. No.: 11/439,410

(22) Filed: May 23, 2006

Related U.S. Application Data
(63) Continuation-in-part of application No. 11/387,626, filed on Mar. 23, 2006.

(51) Int. Cl. H03H 11/26

(52) U.S. Cl. 327/276

(57) ABSTRACT

A digital-to-time converter (DTC) is provided, made from a plurality of series-connected cells. Each cell has an input interface to accept a signal, a control interface to accept a digital command, a delayed signal path, a minimum delay signal path, and an output interface. The signal path is selected in response to the command. The time delay associated with the delayed signal path of each cell can be varied, so that the plurality of series-connected cells is able to provide a large range of delay combinations. For example, if there are n series-connected cells, then the jth series-connected cell, where j varies from 1 to n, conducts the signal through 2^{j} MOS gates in the delayed signal path. Assuming a digital control word with n bit places, the jth series-connected cell accepts the jth bit place of the control word to select a delay path.

### RELATED APPLICATIONS

This application is a continuation-in-part of a pending patent application entitled, TWO-TRANSISTOR TRI-STATE INVERTER, invented by Afentakis et al., Ser. No. 11/387,626, filed Mar. 23, 2006, Attorney Docket No. SLA8009. This application is incorporated herein by reference.

### BACKGROUND OF THE INVENTION

1. Field of the Invention

This invention generally relates to electronic time delay circuitry and, more particularly, to a digital-to-time converter (DTC) with digitally controlled linear time delay.

2. Description of the Related Art

Digitally-controlled delay lines, or digital-to-time converters find application in variable-phase clock generation circuits, direct digital synthesis (DDS) circuits, digital modulator/demodulator and frequency synthesizer architectures, time-frequency conversion modules, and other circuits that require the generation of accurate time-referenced signals.

Conventionally, a variable delay is generated employing a delay stage, such as a source-coupled delay cell, a cross-coupled delay cell, or a current-starved inverter delay cell, which is modified to accept multiple control inputs. These control input represents the bits of the digital control word, and they activate appropriately sized transistors. The delay of any of the aforementioned stages can be approximated as an RC product; the digital input activates the series-R or the C-load of this configuration, generating the desired delay.

FIG. 1 is a schematic diagram of a digital-to-time circuit enabled with a current-starved inverter delay cell (prior art). A variable delay is generated between Vᵢₙ and Vₒᵤₜ, in response to the digital control word C₀C₁C₂C₃ (4 bits). This is a generic design, which makes use of both series-R and C-load manipulation for delay generation. The p-channel metal/oxide/semiconductor (PMOS) and n-channel MOS (NMOS) transistors that receive inputs C₀, C₁, C₂, C₃ are appropriately scaled, assuming the C₀ is the least significant bit (LSB), the transistor channel widths (W) are scaled to the channel length (L) as W/L, 2W/L, 4W/L, and 8W/L, respectively, from the LSB to the most significant bit (MSB).

FIG. 1 also shows a variable capacitive load. Although not specifically shown, a capacitive load is usually implemented as a group of capacitor-connected transistors, similar to the connection of the control word transistors; with the sources of each transistor connected in parallel, the drain regions of each transistor connected together in parallel to the Vₒᵤₜ line, and each gate connected to a different control bit. Again, appropriately scaled gate widths can be used give different total capacitance values for each digital input combination.

Alternately but not shown, a digital-to-time conversion is performed by comparing a linearly increasing voltage or current ramp to a threshold voltage or current. In another aspect, a fixed threshold voltage is compared to a ramp voltage having a variable slope. The slope of the ramp voltage is determined from the value of the digital control word. In a different aspect, a ramp voltage with a fixed slope is compared to a variable threshold voltage whose level is determined in accordance with the digital control word. In any of these cases, when the ramp voltage equals the value of the threshold voltage, an output signal is generated, with the time between the start of the ramp signal and the pulse signal representing the value of the digital control word.

The ramp voltage can be generated by charging a ramp capacitor with a current whose value is determined by a ramp resistor. The ramp resistor and/or the ramp capacitor can be made externally selectable to provide different time delay ranges. For large values of the ramp resistor, the charging current is small, and normally negligible transistor base currents in the voltage coupling circuit become an appreciable percentage of the charging capacitor current. Such transistor base currents cause the ramp slope to differ from the desired slope, producing errors in the output time delay.

FIG. 9 is a schematic diagram of a source-coupled (SC) delay cell (prior art). This cell accepts differential input signals and supplies differential output signals. The input signal (Vᵢₙ+) and its inverse (Vᵢₙ−) are supplied to the gates of M2 and M3, respectively. The output signal (Vₒᵤₜ+) and its inverse (Vₒᵤₜ−) are obtained from the drains of M2 and M3. Transistor M1 acts as a current source, supplying current through the pairs M2/M4 and M3/M5. Transistors M4 and M5 operate in their linear region, thus, their drain-to source resistance in proportional to the applied control bias V_{c}. As a result, V_{c} can be used to control the RC delay of this cell.

FIG. 10 is a schematic diagram of a cross-coupled (CC) delay cell (prior art). This cell also uses differential inputs and outputs. M3 and M4 are the input transistors. M1 and M2 form a regenerative latch, as their gates are connected to the output nodes, through M6 and M5, respectively. Transistors M6 and M5 control the peak voltage that is seen at the gates of the M1 and M2 latch. Increasing the control voltage V_{c} leads to a higher peak voltage at the gates of M1 and M2 and, consequently, to shorter cell delay.

As can be appreciated from the above discussion, significant timing errors may accrue from variations in transistor characteristics. Even if fabrication tolerances are tightly controlled, many conventional delay designs rely upon controlled variations in the transistor gate widths used, which add extra steps and costs in the manufacture of circuits.

It would be advantageous if a DTC circuit could be fabricated from transistors having identical geometries to minimize fabrication expenses and tolerance errors.

### SUMMARY OF THE INVENTION

This present invention presents a digitally-controlled architecture for variable delay generation, which is inherent linear. The architecture can be implemented using any of the aforementioned conventional delay cells. The inherent linearity stems from the use of serial connected cells, where each cell offers the choice of parallel delay paths, and the overall delay is built through a digital selection of a particular number of gates, each having a uniform delay.

Accordingly, a digital-to-time converter (DTC) is provided. The DTC is made from a plurality of series-connected cells. Each cell has an input interface to accept a signal, a control interface to accept a command, a delayed signal path, a minimum delay signal path, and an output interface. Each cell directs the signal from the input interface to the output interface via a signal path selected in response to the command.

Using a current-starved delay cell as an example, each cell delayed signal path includes a plurality of sequentially-connected metal/oxide/semiconductor (MOS) transistors with a source/drain (S/D) region of a previous MOS transistor connected to a gate of a subsequent MOS transistor. The delayed signal path is enabled by selectively supplying dc power to the plurality MOS transistors in response to a (digital control word bit) command. In one aspect, the NMOS and PMOS transistors are series connected as tri-state inverters, and interposed between NMOS and PMOS control transistors. The control PMOS has S/D regions series connecting the PMOS inverter transistor to a supply voltage and a gate to receive the command. The control NMOS transistor has S/D regions series connecting the NMOS inverter transistor to a reference voltage, and a gate to receive an inverted command.

Further, the time delay associated with the delayed signal path of each cell can be varied, so that the plurality of series-connected cells is able to provide a large range of delay combinations. For example, if there are n series-connected cells, then the jth series-connected cell, where j varies from 1 to n, conducts the signal through 2/MOS gates in the delayed signal path. Assuming a digital control word with n bit places, the jth series-connected cell accepts the jth bit place of the control word, selects the minimum delay signal path in response to a “0” command, and selects the delayed signal path in response to a “1” command.

Additional details of the above-described DTC and a method for selectively delaying a signal using a MOS transistor circuit are provided below.

### BRIEF DESCRIPTION OF THE DRAWINGS

FIG. 1 is a schematic diagram of a digital-to-time circuit enabled with a current-starved inverter delay cell (prior art).

FIG. 2 is a schematic block diagram of a digital-to-time converter (DTC).

FIG. 3 is a schematic diagram depicting series-connected cells enabled in a current-starved tri-state inverter design.

FIG. 4 is a diagram depicting the tri-state inverter stage 300a, 300b, 300c, and 300d of FIG. 3 enabled with dual-gate thin-film transistors (DG-TFTs).

FIG. 5 is a schematic block diagram depicting two delay cells controlled by a 2-bit digital word (AB).

FIG. 6 is a schematic block diagram depicting the circuit of FIG. 5 with complementary switching.

FIG. 7 is a schematic block diagram depicting the circuit of FIG. 6 with a buffer in the minimum delay path.

FIG. 8 is a flowchart illustrating a method for selectively delaying a signal in a MOS transistor circuit.

FIG. 9 is a schematic diagram of a source-coupled (SC) delay cell (prior art).

FIG. 10 is a schematic diagram of a cross-coupled (CC) delay cell (prior art).

### DETAILED DESCRIPTION

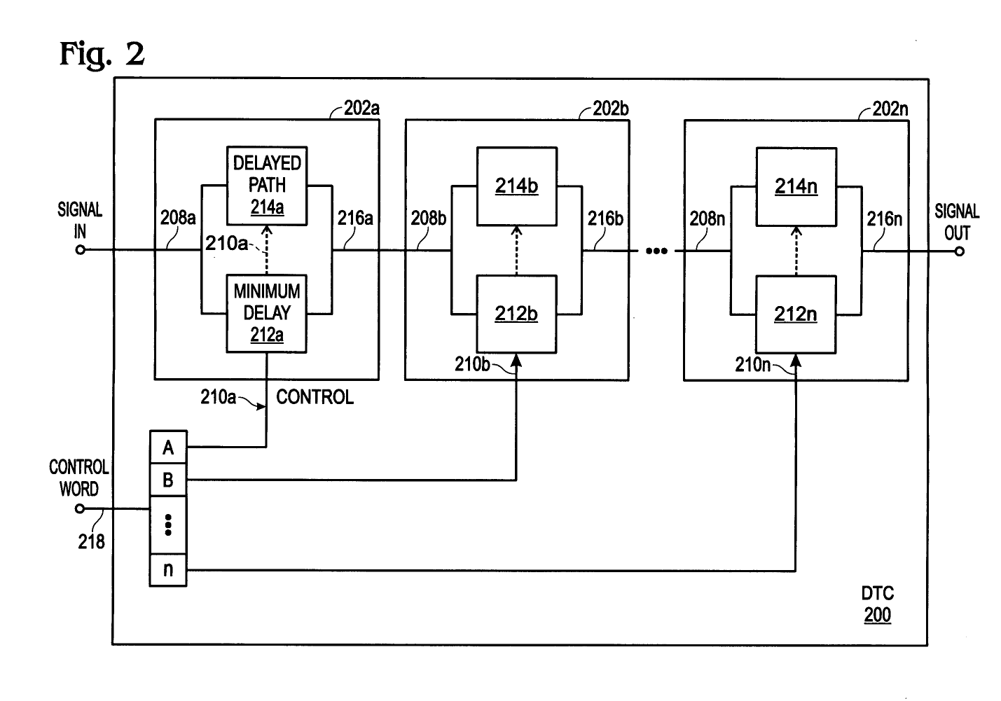

FIG. 2 is a schematic block diagram of a digital-to-time converter (DTC). The DTC 200 comprises a plurality of series-connected cells 202. Shown are cells 202a, 202b, and 202n, representing n cells, where n is not limited to any particular number. For simplicity, n is shown as equal to 3. Each cell has an input interface 208 to accept a signal, a control interface 210 to accept a command, a delayed signal path 212, a minimum delay signal path 214, and an output interface 216. For example, cell 202a directs the signal from the input interface 208a to the output interface 216a via a signal path selected in response to the command received at the control interface 210a. Cell 202a directs the signal from the input interface 208a to the output interface 216a via the delayed signal path 214a by enabling the delayed signal path 214a and disabling the minimum delay signal path 212a. Likewise, the signal is directed via the minimum delay signal path by enabling minimum delay path 212a and disabling delayed signal path 214a.

Further, the time delay associated with the delayed signal path of each cell can be varied, so that the plurality of series-connected cells is able to provide a large range of delay combinations. For example, the delayed signal path 214a of cell 202a may have a first time delay, while the delayed signal path 214b of cell 202b may have a second time delay, less (or greater) than the first time delay.

Assuming n series-connected cells, then the jth series-connected cell, where j varies from 1 to n, conducts the signal through 21 MOS gates in the delayed signal path. For example, for cell 206 j is equal to 3, so that the delayed signal path has 2³=8 MOS gates worth of delay. As explained in more detail below, the delay is a result of 8 identical delay stages. Also as explained below, for the purposes of loading and impedance matching the minimum delay path may include a delay of one MOS gate, so that the maximum delay associated with the jth cell is described as 2^{j}+1.

In one aspect, the DTC 200 has a port 218 to accept a digital control word with n bit places. Then, the jth series-connected cell accepts the jth bit place of the digital control word at the control interface 210, selects the minimum delay signal path in response to a “0” command, and selects the delayed signal path in response to a “1” command.

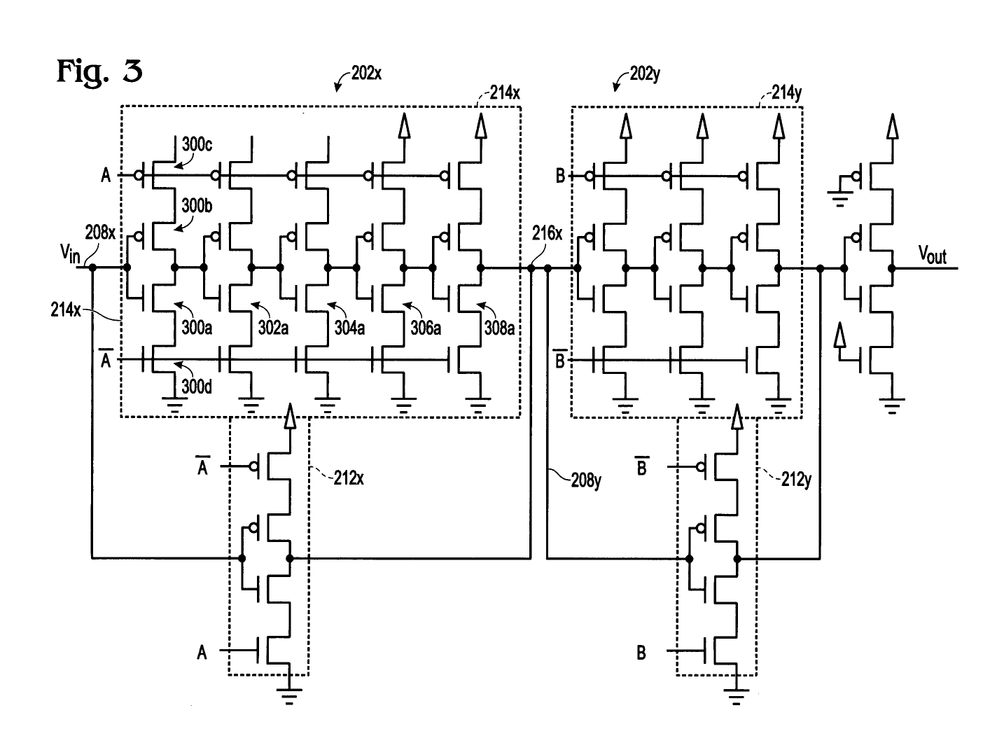

FIG. 3 is a schematic diagram depicting series-connected cells enabled in a current-starved tri-state inverter design. Generally, each delayed signal path 214 includes a plurality of sequentially-connected metal/oxide/semiconductor (MOS) transistors with a source/drain (S/D) region of a previous MOS transistor connected to a gate of a subsequent MOS transistor. For example, delayed signal path 214x includes a chain of 5 sequentially-connected MOS field effect transistors (MOSFETs) 300, 302, 304, 306, and 308. A S/D region of the first transistor in the chain, MOSFET 300, is connected to the gate of the second MOSFET 302. The delayed signal path 214x is enabled by selectively supplying dc power to the plurality MOS transistors 300-308 in response to the command (A and A).

In one aspect as shown, delayed signal paths 214x and 214y are a plurality of sequentially-connected tri-state inverters with an initial tri-state inverter gate connected to the cell input 208. The S/D region of a previous tri-state inverter is connected to the gate of a subsequent tri-state inverter, and the S/D region of a final inverter connected to the cell output 216. More explicitly, each tri-state inverter in delayed signal path 214x includes an n-channel MOS (NMOS) inverter transistor and a p-channel MOS (PMOS) inverter transistor with parallel-connected gates to receive a signal. The NMOS and PMOS transistors have series-connected S/D regions to supply an inverted signal, a control input to accept the command (A), and a control input to accept an inverted command (A). Circuitry not shown accepts the control word bits A and B, and provides inverted control words. Alternately, the DTC may accept inverted control word bits, and circuitry (not shown) converts the inverted control word bits to (non-inverted) control word bits.

For example, NMOS 300a and PMOS 300b form a tri-state inverter. The S/D regions of tri-state inverter 300 is connected to the gate of a subsequent tri-state inverter 302, and the S/D region of a final inverter 308 is connected to the cell output 216x.

Each delayed signal path tri-state inverter also includes a control PMOS transistor with S/D regions series connecting the PMOS inverter transistor to a supply voltage. The control PMOS also has a gate to receive the command (A). A control NMOS transistor has S/D regions series connecting the NMOS inverter transistor to a reference voltage, lower in voltage than the supply voltage, and a gate to receive the inverted command ( A̅). To continue the example, control PMOS 300c is series-connected to PMOS 300b, and control NMOS 300d is series-connected to NMOS 300a.

FIG. 4 is a diagram depicting the tri-state inverter stage 300a, 300b, 300c, and 300d of FIG. 3 enabled with dual-gate thin-film transistors (DG-TFTs). As described in more detail in pending parent patent application entitled, TWO-TRANSISTOR TRI-STATE INVERTER, a conventional four-transistor tri-state inverter can be replaced by two series connected DG-TFTs. Thus, the delayed signal path NMOS inverter transistor (300a, see FIG. 3) and NMOS control transistor (300d) can be replaced by is a DG-TFT NMOS 400 with a top gate 402 to receive the input signal and a bottom gate 404 to receive the inverted command ( A̅). Likewise, delayed signal path PMOS inverter transistor (300b, see FIG. 3) and PMOS control transistor (300c) can be replaced with a DG-TFT PMOS 406 with a top gate 408 parallel-connected to the NMOS DG-TFT top gate 402, and a bottom gate 410 to receive the command (A).

Returning to FIG. 3, each minimum delay signal path 212 includes a MOS transistor with a gate connected to the cell input and a S/D region connected to the cell output. For example, transistor 312 has a gate connected to input 208x, and a S/D region connected to output 216x. In one aspect as shown, the delay signal path MOS transistor 312 gate is connected to the gates of the initial tri-state inverter (300a and 300b) in the delayed signal path 214x, and the S/D region is connected to the S/D region of a final tri-state inverter 310 in the delayed signal path.

More explicitly, minimum delay signal path 212x includes a tri-state inverter with an NMOS inverter transistor 312a and a PMOS inverter transistor 312b with parallel-connected gates to receive the signal on line 208x. Transistors 312a and 312b have series connected S/D regions to supply an inverted signal on line 216x, a control input to accept the command (A), and a control input to accept an inverted command ( A̅). A control PMOS transistor 312c has S/D regions series connecting the PMOS inverter transistor 312b to a supply voltage, and a gate to receive the inverted command ( A̅). Likewise, a control NMOS transistor 312d has S/D regions series connecting the NMOS inverter transistor 312a to a reference voltage, lower in voltage than the supply voltage, and a gate to receive the command (A). As shown in FIG. 4, tri-state inverter transistors 312a, 312b, 312c, and 312d, can be replaced with two series-connected DG-TFTS, so that the NMOS and PMOS top gates receive the input signal on line 208x, the NMOS bottom gate receives the command (A), and the PMOS bottom gate received the inverted command ( A̅).

In one aspect, each minimum delay signal path MOS transistor has a first gate width, and each delayed signal path MOS transistor has the (same) first gate width. Since the delay associated with each transistor gate is the same, the desired overall delay through the DTC can be configured by using a digital control word to simply select the required number of gates. In another aspect, the DTC can be designed to have the delay granularity equal to the delay associated with a single gate.

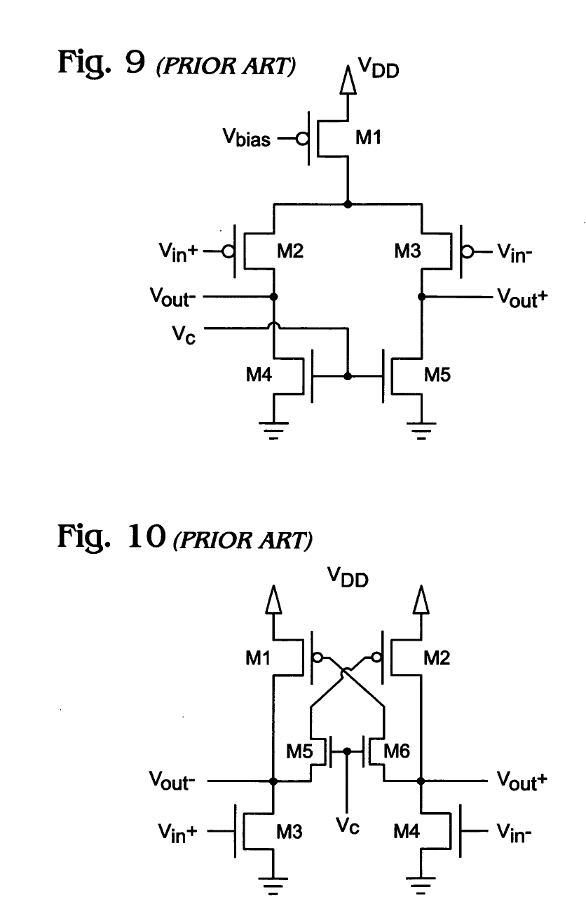

It should be understood that although a current-starved design has been used to illustrate the invention, the invention can be applied to CMOS pass gates, source-coupled gates (see FIG. 9), cross-coupled gates (see FIG. 10), and other means of sequentially chaining MOS transistor gates. Further, although an inverting gate has been specifically depicted, the invention may also be enabled using non-inverting gates. Although MOS circuitry is shown, the present invention is also applicable to bipolar transistor technology.

### Functional Description

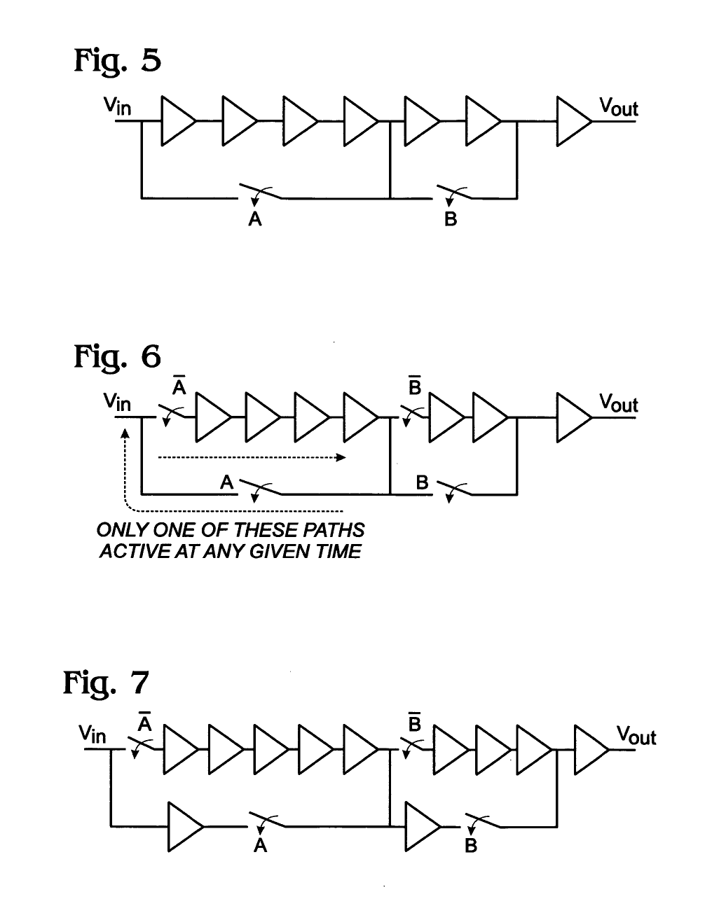

FIG. 5 is a schematic block diagram depicting two delay cells controlled by a 2-bit digital word (AB). Identical inverting or non-inverting buffer stages are used, with the maximum delay being 7 stages and the minimum delay equal to 1 stage. The amount of time delay from Vᵢₙ to Vₒᵤₜ is controlled by the 2-bit digital input word AB (A=MSB, B=LSB). The desired amount of time delay is generated by setting the effective number of buffer (or delay) cells from Vᵢₙ to Vₒᵤₜ. This delay is achieved by using the bits of the digital control word to “short” a particular number of buffer cells. The number of cells shorted increases as the significance of each control bit increases. Thus, the LSB shorts the least number of stages, and the MSB shorts the most number of stages.

In a simple implementation (not shown), the total number of delay cells equals 2, with the total number of stages n=4. Control bit A (MSB) shorts 2 stages, bit B (LSB) shorts 1 stage, and there is a minimum one-stage delay.

In the two delay cell implementation shown in FIG. 5, the number of stages n=7. Control word bits A and B short 4 and 2 stages, respectively. Assuming that a control word bit value of “1” means that a corresponding switch is closed, the DTC delay characteristics are summarized in Table 1.

TABLE 1

| A | B | Effective # of stages |
|---|---|---|
| 0 | 0 | 7 |
| 0 | 1 | 5 |
| 1 | 0 | 3 |
| 1 | 1 | 1 |

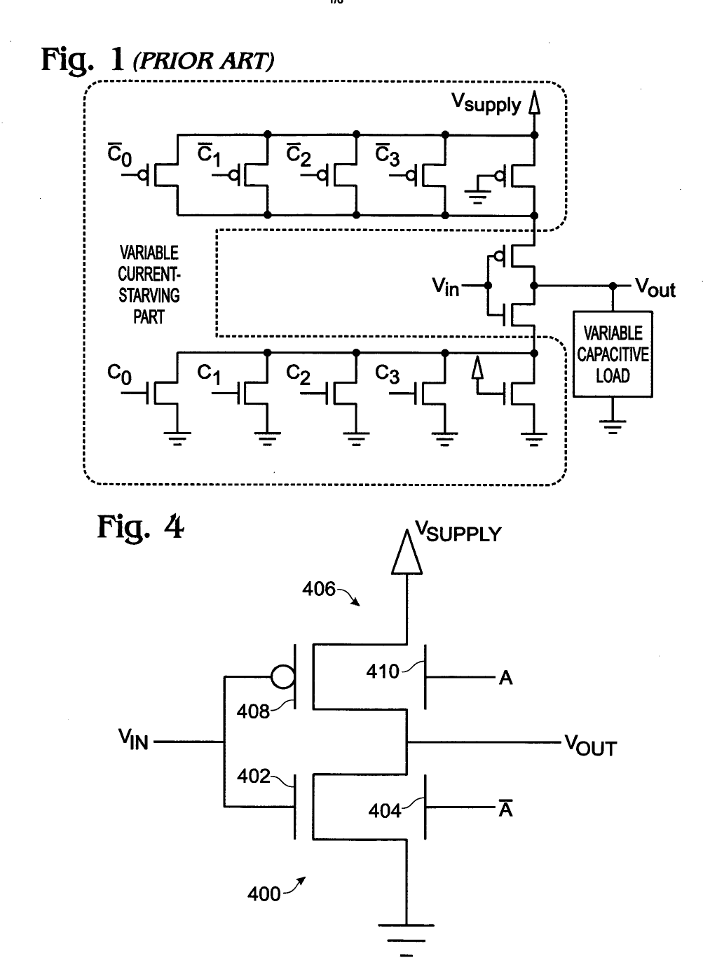

One feature of the present invention is that the total delay is (ideally) a linear function of the digital control word, because the control word is a linear function of the effective number of delay stages, assuming that all stages (the minimum delay increment) are identical. The linearity of the DTC is improved if the stages are fabricated with identical geometries, as transistors with scaled channel areas (as required in the prior art implementation of FIG. 1) necessarily exhibit threshold voltage and effective mobility variations.

In another aspect not shown, hex inverters can be used to form a ring oscillator by closing the loop between Vᵢₙ and Vₒᵤₜ. In this application, each switch shorts an even number of stages (as shown in FIG. 5), in order to maintain an odd number of effective stages. This way, an oscillator is constructed with its frequency being inversely proportional to the digital input.

The present invention design is easily scaled up for larger sized digital control words. For linearity, the LSB is used to short n number of stages, the next significant bit shorts 2n stages, and so forth.

FIG. 6 is a schematic block diagram depicting the circuit of FIG. 5 with complementary switching. In this design, the shorts are activated in a complementary way, and signal racing is prevented by having only one branch of each group of delay element active when the corresponding control bit is active.

FIG. 7 is a schematic block diagram depicting the circuit of FIG. 6 with a buffer in the minimum delay path. As another refinement, buffer/delay cells can be placed in each of the shorted buffer group paths. This way, the same input and output impedances are presented, regardless of the path selected. Of course, the addition of an extra stage on the “shorting” (minimum delay) path necessitates the addition of another stage within the “shorted” (delayed signal path) group, in order to maintain the linear operation of the circuit. That is, as extra stage must be added to the delayed signal path to maintain the LSB granularity of a stage delay.

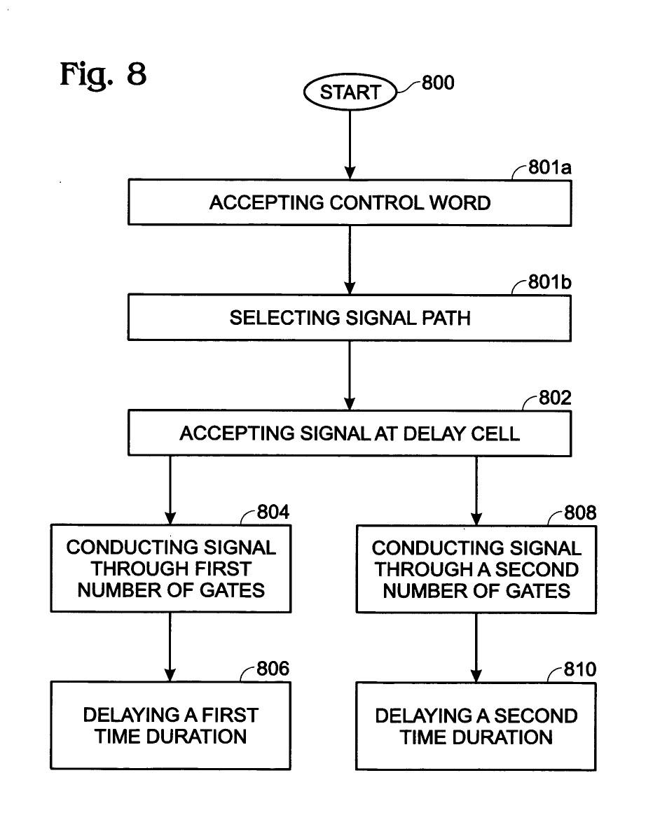

FIG. 8 is a flowchart illustrating a method for selectively delaying a signal in a MOS transistor circuit. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. The method starts at Step 800.

Step 802 accepts a signal at a delay cell with parallel signal paths. Step 804 conducts the signal through a first number of MOS gates in response to selecting a first signal path. Step 806 delays the signal a first time duration. Step 808 conducts the signal through a second number of MOS gates, greater than the first number, in response to selecting a second signal path. Step 810 delays the signal a second time duration, greater than the first time duration.

In one aspect, Step 801a accepts a digital control word. Step 801b selects a signal path in response to the control word by enabling MOS transistors in the selected signal path, and disabling MOS transistors in the non-selected signal path.

In another aspect, supplying the signal to the delay cell in Step 802 includes supplying the signal to a jth series-connected cell, where j varies from 1 to n, of n series-connected cells. Then, conducting the signal through the second number of MOS gates (Step 808) includes conducting the signal through 2^{j} MOS gates.

Further, if Step 801a accepts a digital control word with n bit places, then for the jth cell, Step 801b selects a signal path in response to the jth bit place in the control word.

A DTC circuit has been presented with the features of parallel delay paths, and linear digital control of delay based upon the uniform, least significant delay unit of a single gate. Current-starved and tri-state inverter examples have been presented to illustrate the invention. However, the invention is not limited to merely these examples. Other variations and embodiment of the invention will occur to those skilled in the art.

We claim:

1. A digital-to-time converter (DTC) comprising:
a plurality of series-connected cells;
each cell having an input interface to accept a signal, a control interface to accept a command, a delayed signal path, a minimum delay signal path, and an output interface; and,
wherein each cell directs the signal from the input interface to the output interface via a signal path selected in response to the command.

2. The DTC of claim 1 wherein the plurality of series-connected cells includes a first cell and a second cell;
wherein the first cell has a first delayed signal path with a first time delay; and,
wherein the second cell has a second delayed signal path with a second time delay, greater than the first time delay.

3. The DTC of claim 1 wherein each cell directs the signal from the input interface to the output interface via the delayed signal path by:
enabling the delayed signal path; and,
disabling the minimum delay signal path.

4. The DTC of claim 3 wherein each delayed signal path includes a plurality of sequentially-connected metal/oxide/semiconductor (MOS) transistors with a source/drain (S/D) region of a previous MOS transistor connected to a gate of a subsequent MOS transistor.

5. The DTC of claim 4 wherein the delayed signal path is enabled by selectively supplying dc power to the plurality MOS transistors in response to the command.

6. The DTC of claim 5 wherein each delayed signal path includes a plurality of sequentially-connected tri-state inverters with:
an initial tri-state inverter gate connected to the cell input;
a S/D region of a previous tri-state inverter connected to the gate of a subsequent tri-state inverter; and,
a S/D region of a final inverter connected to the cell output.

7. The DTC of claim 6 wherein each delayed signal path tri-state inverter includes an n-channel MOS (NMOS) inverter transistor and a p-channel MOS (PMOS) inverter transistor with parallel-connected gates to receive a signal, series connected S/D regions to supply an inverted signal, a control input to accept the command, and a control input to accept an inverted command.

8. The DTC of claim 7 wherein each delayed signal path tri-state inverter includes:
a control PMOS transistor with S/D regions series connecting the PMOS inverter transistor to a supply voltage, and a gate to receive the command; and,
a control NMOS transistor with S/D regions series connecting the NMOS inverter transistor to a reference voltage, lower in voltage than the supply voltage, and a gate to receive the inverted command.

9. The DTC of claim 7 wherein the delayed signal path NMOS inverter transistor is a dual-gate thin-film transistor (DG-TFT) NMOS with a top gate to receive the signal and a bottom gate to receive the inverted command; and,
wherein the delayed signal path PMOS inverter transistor is a DG-TFT PMOS with a top gate parallel-connected to the NMOS DG-TFT and a bottom gate to receive the command.

10. The DTC of claim 7 wherein each minimum delay signal path includes a MOS transistor with a gate connected to the cell input and a S/D region connected to the cell output.

11. The DTC of claim 10 wherein each minimum delay signal path MOS transistor gate is connected to the gates of the initial tri-state inverter in the delayed signal path, and the S/D region is connected to the S/D region of a final tri-state inverter in the delayed signal path.

12. The DTC of claim 10 wherein each minimum delay signal path includes a tri-state inverter with an NMOS inverter transistor and a PMOS inverter transistor with parallel-connected gates to receive the signal, series connected S/D regions to supply an inverted signal, a control input to accept the command, and a control input to accept an inverted command.

13. The DTC of claim 12 wherein each minimum delayed signal path tri-state inverter includes:
a control PMOS transistor with S/D regions series connecting the PMOS inverter transistor to a supply voltage, and a gate to receive the inverted command; and,
a control NMOS transistor with S/D regions series connecting the NMOS inverter transistor to a reference voltage, lower in voltage than the supply voltage, and a gate to receive the command.

14. The DTC of claim 12 wherein the minimum delay signal path NMOS inverter transistor is a dual-gate thin-film transistor (DG-TFT) with a top gate to receive the signal and a bottom gate to receive the command; and,
wherein the minimum delay signal path PMOS inverter transistor is a DG-TFT with a top gate parallel-connected to the NMOS DG-TFT, and a bottom gate to receive the inverted command.

15. The DTC of claim 5 wherein each minimum delay signal path MOS transistor has a first gate width; and,
wherein each delayed signal path MOS transistor has the first gate width.

16. The DTC of claim 15 the plurality of series-connected cells equals n series-connected cells, and,
wherein the jth series-connected cell, where j varies from 1 to n, conducts the signal through 21 MOS gates in the delayed signal path.

17. The DTC of claim 11 further comprising:
a port to accept a digital control word with n bit places; and,
wherein the jth series-connected cell accepts the jth bit place of the digital control word at the control interface, selects the minimum delay signal path in response to a “0” command, and selects the delayed signal path in response to a “1” command.

18. In a metal/oxide/semiconductor (MOS) transistor circuit, a method for selectively delaying a signal, the method comprising:
accepting a signal at a delay cell with parallel signal paths;
in response to selecting a first signal path, conducting the signal through a first number of MOS gates;
delaying the signal a first time duration;
in response to selecting a second signal path, conducting the signal through a second number of MOS gates, greater than the first number; and,
delaying the signal a second time duration, greater than the first time duration.

19. The method of claim 18 further comprising:
accepting a digital control word;
selecting a signal path in response to the control word as follows:
enabling MOS transistors in the selected signal path; and,
disabling MOS transistors in the non-selected signal path.

20. The method of claim 19 wherein accepting the signal at the delay cell with parallel signal paths includes accepting the signal at a jth series-connected cell, where j varies from 1 to n, of n series-connected cells, and,
wherein conducting the signal through the second number of MOS gates, in response to selecting the second signal path, includes conducting the signal through 2^{j} MOS gates.

21. The method of claim 20 wherein accepting the digital control word includes accepting a control word with n bit places; and,
wherein selecting the signal path in response to the control word includes, for the jth cell, selecting a signal path in response to the jth bit place in the control word.
